(19) United States
(12) Patent Application Publication
(10) Pub. No.: US 2026/0246371 A1
(43) Pub. Date: Aug. 20, 2026

(54) SWITCHING CIRCUIT, CORRESPONDING DEVICE AND METHOD

(71) Applicant: STMicroelectronics International N.V., Geneva (CH)

(72) Inventors: Giovanni GONANO, Milano (IT); Edoardo BOTTI, Vigevano (PAVIA) (IT)

(73) Assignee: STMicroelectronics International N.V., Geneva (CH)

(21) Appl. No.: 19/540,907

(22) Filed: Feb. 16, 2026

(30) Foreign Application Priority Data
Feb. 17, 2025 (IT) 102025000003012

(51) Int. Cl. H02M 1/38; H02M 1/00; H02M 1/08; H02M 3/158; H03F 3/217

(52) U.S. Cl. CPC H02M 1/38; H02M 1/0009; H02M 1/08; H02M 3/158; H03F 3/217; H03F 3/2173

(57) ABSTRACT

A circuit includes a switching stage with first and second half bridges, each containing a high-side and a low-side DMOS transistor. Output nodes between these transistors supply an electrical load via filter networks. Control circuitry manages switching sequences, alternating pairs of DMOS transistors between conductive and non-conductive states across the half bridges. The circuit features a current flow line with an inductance, connected to two switches that can be set to conductive or non-conductive states. First and second capacitances are coupled to the output nodes of each half bridge. The control circuitry switches the two switches to the conductive state at specific intervals during the switching sequence, based on transitions between transistor pairs. Additionally, control signals for these switches are determined by the delay between output signals at the respective output nodes.

### PRIORITY CLAIM

This application claims the priority benefit of Italian Application for Patent No. 102025000003012, filed on Feb. 17, 2025, the content of which is hereby incorporated by reference in its entirety to the maximum extent allowable by law.

### TECHNICAL FIELD

The description relates to switching circuits. One or more embodiments may be applied, for example, to switching audio power amplifiers such as Class D amplifiers.

### BACKGROUND

Efficiency and low distortion are key figures of merit in switching circuits, such as class D audio power amplifiers.

A fixed-frequency class D bridge audio amplifier with reduced switching losses (ZSL) and reduced total harmonic distortion (THD) is described in United States Application for Patent No. 2019/0238094 (the contents of which is incorporated by reference in its entirety), which discusses a ZSL switching circuit including a switching circuit stage configured to supply a load via filter networks. Control circuitry is provided to control alternate switching sequences of transistors in the half-bridges of the switching circuit stage. A current flow line is provided between the output nodes of the half-bridges, including an inductance between two switches. First and second capacitances are coupled with the output nodes of the half-bridges. The control circuitry switches the first and second switches to the conductive state at intervals in the alternate switching sequences of the transistors in the half-bridges, between switching the first pair of transistors to a non-conductive state and switching the second pair of transistors to a conductive state.

In power stages using silicon technology currently referred to as integrated Double-diffused Metal-Oxide Semiconductor (DMOS), two primary types of parasitic diodes are referred to as the Sub-Body-Drain diode (SubBD) and the Body-Drain diode (DBD). These diodes are intrinsic to the DMOS structure and play respective roles in the device's operation, particularly in handling voltage stress and current flow during switching operations.

The Body-Drain diode (DBD) is a parasitic diode between the body and the drain of the DMOS transistor, due to the PN junction formed there. The DBD diode is forward-biased when the body is at a higher potential than the drain, allowing current to flow from the body to the drain. In power stages, the DBD provides a path for freewheeling currents during the off-state of the transistor. It has an impact in applications like class D amplifiers and power converters, where inductive loads can cause current to continue flowing even when the transistor is turned off.

The Sub-Body-Drain (SubBD) diode is similar to the DBD diode and is associated with more complex DMOS structures, often influenced by additional doping or layout variations that affect the junction characteristics. The SubBD diode can provide additional pathways for current, potentially impacting the overall efficiency and thermal performance of the DMOS device. It has an impact in designs aiming to manage high-voltage stress and improve the reliability of the power stage by distributing voltage drops across multiple junctions.

Both DBD and SubBD diodes affect DMOS device operation, particularly under various electrical stresses, helping to manage issues like reverse voltage protection and current continuity in inductive circuits. They also influence the overall efficiency and reliability of power stages, especially in applications that demand high-speed switching and minimal power loss.

Therefore, the above-mentioned diodes are taken into account in the design of power electronics systems using integrated DMOS devices.

For instance, when currents trigger deep forward conduction of DMOS diodes during DMOS reverse conduction, the ZSL circuit may become unbalanced due to the different charge storage in the SubBD diode and DBD diode of the high-side and low-side conducting DMOS transistors of the integrated circuit. During the reverse conduction phase, while high-side (HS) and low-side (LS) DBDs are both conducting, the SubBD junction of the LS DMOS is also conducting. As the SubBD diode has a quite different transition time compared to the DBD diode, this can result in a difference in the stored charge and its release time.

LS and HS DBDs might have different dissipation conditions, as a DMOS located at the corner of a semiconductor die can have a higher thermal resistance than one placed in the center, resulting in different operating temperatures. Since diode conduction is highly dependent on temperature, an imbalance can exist.

Asymmetric packaging can further generate different electrical conditions (e.g., due to different bonding wire lengths or metallization).

Existing solutions are discussed in the following documents:

United States Application for Patent No. 2019/0238094 (the content of which is incorporated by reference in its entirety) discusses a switching circuit including a switching circuit stage configured to supply a load via filter networks; control circuitry is provided to control alternate switching sequences of transistors in the half-bridges of the switching circuit stage; a current flow line is provided between the output nodes of the half-bridges, including an inductance between two switches; first and second capacitances are coupled with the output nodes of the half-bridges; the control circuitry switches the first and second switches to the conductive state at intervals in the alternate switching sequences of the transistors in the half-bridges, between switching the first pair of transistors to a non-conductive state and switching the second pair of transistors to a conductive state.

United States Application for Patent No. 2019/0386615 (the content of which is incorporated by reference in its entirety) discusses an oscillator including a constant current generator configured to generate a constant current by maintaining a predetermined potential difference between both a first end and a second end of a resistor, and an oscillating element configured to output a clock signal corresponding to a charge and discharge cycle of a capacitor based on a bias current corresponding to the constant current.

United States Application for Patent No. 2023/0208413 (the content of which is incorporated by reference in its entirety) discusses a comparator circuit including a first comparator configured to compare a voltage based on an input voltage with a first reference voltage, a charge/discharge portion configured to switch between charging and discharging of a capacitor based on an output of the first comparator, a second comparator configured to compare a voltage of the capacitor with a second reference voltage, and a control portion. The control portion is configured, in a case where the voltage of the capacitor is larger than a predetermined value when the charge/discharge portion switches from charging to discharging, to supply a predetermined voltage instead of the voltage based on the input voltage to the first comparator until the voltage of the capacitor becomes smaller than the predetermined value, so that the discharging of the capacitor is maintained by the charge/discharge portion.

United States Application for Patent No. 2020/0321871 (the content of which is incorporated by reference in its entirety) discusses methods, apparatus, systems, and articles of manufacture disclosed to improve power converter ON-time generation, including a phase frequency detector to determine a phase difference between a first signal and a second signal, a first pulse generator to generate a first time signal at a second time, the first time signal associated with a first time delay based on the phase difference, and a second pulse generator coupled to the first pulse generator to generate a second time signal at a third time, the third time after the second time. The second pulse generator obtains a digital word based on the phase difference at a first time, the first time before the second time and the third time, the second time signal associated with a second time delay based on the phase difference.

United States Application for Patent No. 2011/0121797 (the content of which is incorporated by reference in its entirety) discusses a method of controlling a DC-DC converter, which provides for compensation of the loop delay caused by, for instance, delays in operation of the comparator.

There is a need in the art to provide an improved solution with reduced distortion and/or reduced charge stored in the diodes of the power stage. Such a solution helps counter output overshoot in cases of unbalanced power stage circuitry.

### SUMMARY

One or more embodiments may relate to a circuit.

One or more embodiments may relate to a corresponding device (e.g., a class D audio power amplifier).

One or more embodiments may relate to a corresponding method.

One or more embodiments relate to circuits and techniques to reduce imbalance (e.g., overshoot) in output signals of amplifiers using DMOS devices.

Taking into account the fact that diode conduction increases with temperature, further increasing its recovery charge, one or more embodiments counter the effects produced by an imbalance in a ZSL circuit, thereby facilitating countering uncontrolled temperature increases due to regenerative effects, thereby maintaining the maximum power handled by the device, maintaining a stable output commutation speed, countering the degradation of DMOS performance due to output overshoot (e.g., rising above VCC), and reducing unwanted output common mode signal generation.

One or more embodiments further relate to circuits and techniques to reduce charge storage in diodes (e.g., SubBD and DBD) of the power stage.

One or more embodiments facilitate reducing power consumption (e.g., by around 10%).

One or more embodiments facilitate extending the linear range of operation of a ZSL circuit driver (e.g., by reducing the minimum available duty cycle).

### BRIEF DESCRIPTION OF THE DRAWINGS

One or more embodiments will now be described, by way of example only, with reference to the annexed figures, wherein:

FIG. 1 is an exemplary block diagram of a switching circuit, such as a switching amplifier;

FIG. 2 is a circuit diagram;

FIGS. 2A, 2B, and 2C are diagrams exemplary of operating principles;

FIG. 3 includes portions indicated a) to g), which are exemplary of certain signals;

FIG. 4 comprises portions indicated a) and b) and are diagrams of signal waveforms;

FIG. 5 comprises portions indicated a) to g), which are exemplary of certain signals;

FIG. 6 is a diagram exemplary of a circuit operating according to the method herein;

FIG. 7 is a diagram exemplary of a possible operation mode;

FIG. 8 includes portions indicated a) to i), which are exemplary of certain signals;

FIG. 9 includes portions indicated a) to m), which are exemplary of certain signals;

FIG. 10 is a diagram exemplary of operating principles;

FIG. 11 is a diagram exemplary of a circuit; and

FIG. 12 is a diagram exemplary of an alternative circuit;

FIGS. 13 and 14 are diagrams exemplary of certain signals.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

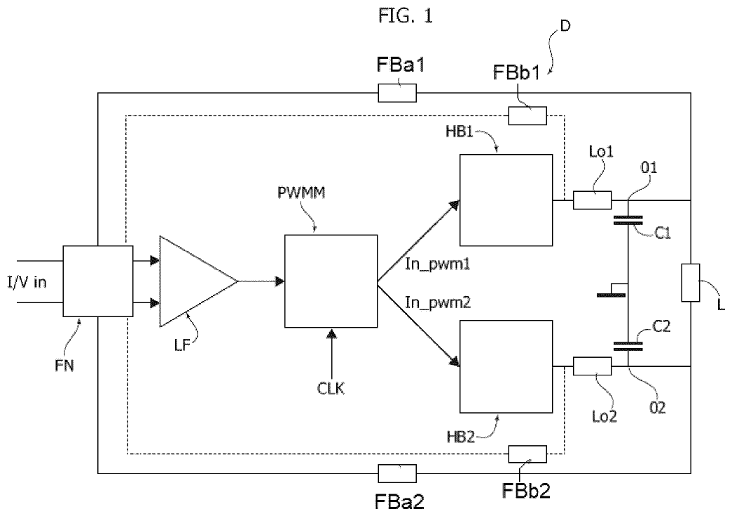

A first exemplary method, circuit, and device according to the present disclosure is illustrated in FIGS. 1 to 7.

FIG. 1 shows exemplary block diagrams of a switching circuit, such as a class D audio amplifier (for example, for use in a car audio system), including a switching bridge architecture.

In such a circuit, a voltage or current input signal (I/V in) is applied, for example via a feedback network (FN), to a loop filter (LF) which facilitates system stability, while negative feedback (as implemented at FN) is intended to improve amplitude and frequency linearity.

As shown in FIG. 1, a set of feedback branches (FBa1, FBa2, FBb1, FBb2) are coupled to an output load (L) and to the feedback network (FN) to facilitate the application of negative feedback.

The output from the loop filter (LF) is fed to a pulse width modulation (PWM) modulator (PWMM) clocked by a clock signal (CLK). The modulator (PWMM) generates a two-level signal whose average value is proportional to the input signal (I/V in), with a fixed-frequency carrier defined by the clock signal (CLK).

Two half-bridge circuits (HB1, HB2), driven by the modulator (PWMM) via two signals (In_pwm1, In_pwm2), provide a PWM-modulated power signal across an LC output filter network comprising, for example, respective inductances (Lo1, Lo2) and capacitances (C1, C2) in a mirror-symmetrical configuration.

In a class D bridge circuit as considered here, the signals In_pwm1 and In_pwm2 (and consequently the outputs from the half-bridges HB1, HB2) will have opposite phases (namely, a 1800 phase shift): that is, one of the signals In_pwm1 and In_pwm2 is a negated replica of the other.

An amplified version of the input signal (I/V in) thus becomes available at a load (L) coupled across a first node (O1) between the inductance (Lo1) and the capacitance (C1), and a second node (O2) between the inductance (Lo2) and the capacitance (C2).

The circuit arrangement shown in FIG. 1 is otherwise conventional in the art, making it unnecessary to provide a more detailed description here.

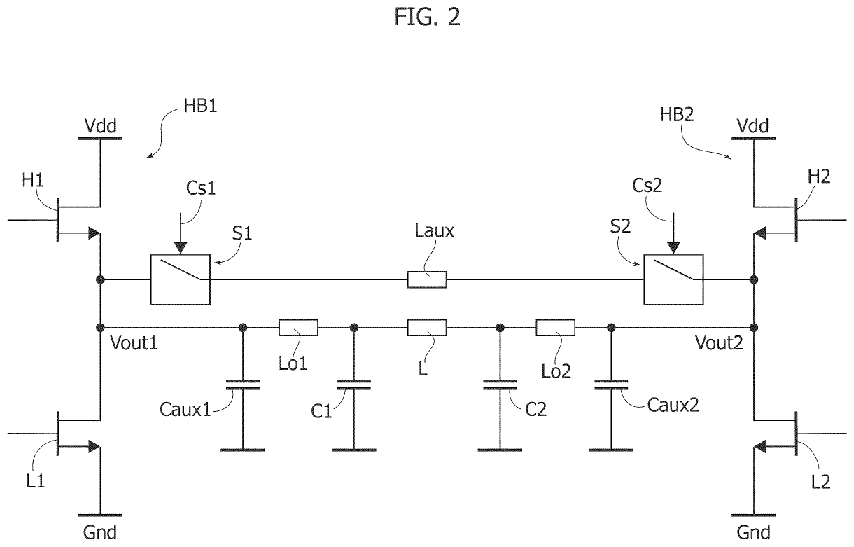

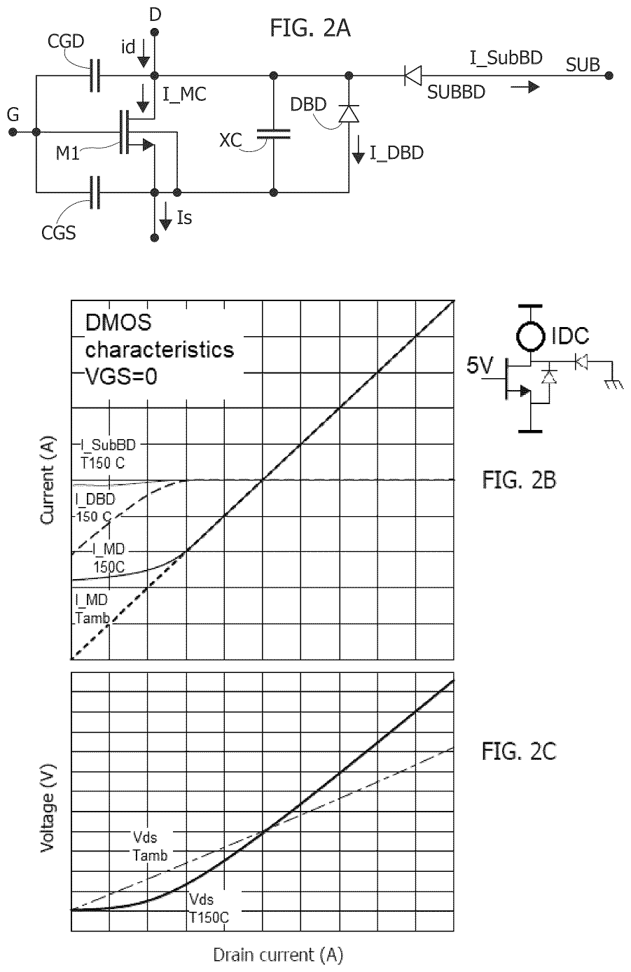

Referring, for instance, to the representation of HB1 and HB2 in FIG. 2 (discussed later), a 1→0 transition in In_pwm1 may turn off a high-side transistor (H1). To avoid cross-conduction with the corresponding low-side transistor (L1), the low-side transistor (L1) is turned on only after a dead time (Dt1).

Due to the direction of current flow, the electromotive force of Lo1 may autonomously bring the output towards ground even though the low-side transistor (L1) has not yet been turned on. As a result, the output is clamped by the body diode associated with L1 to a voltage slightly lower than ground.

Once L1 is turned on (after the dead time Dt1), the signal Vout1 from the half-bridge HB1 reaches a voltage below ground, given by Iout1×Rds(on)H1, where Iout1 denotes the output current and Rds(on)H1 denotes the drain-source “on” resistance of that transistor, namely H1 (e.g., a MOSFET transistor).

When In_pwm1 returns to the high level (0→1), L1 is turned off and the associated body diode becomes conductive again.

Then H1 is turned on again (after a dead time Dt2), and the output will reach the supply voltage (Vdd) only as a result of H1 having completely discharged the recovery stored charge (Qrr) of the body diode of L1. This may give rise to current peaks in H1 largely in excess of Iout1, with associated Vout1 voltage overshoot due to package bonding-leads stray inductance.

The same remarks apply in a complementary way to the half-bridge HB2.

A significant contribution to power dissipation in conventional arrangements as described above is the transition where the transistor being activated discharges the charge stored in the body diode. If the transition is fast, such a current may be appreciably higher than Iout. This leads to correspondingly high power dissipation, as the drain-source voltage (Vds) is nearly equal to Vdd (the supply voltage of the two half-bridges HB1, HB2—see, for example, FIG. 2).

If the two half-bridges HB1, HB2 switch simultaneously, such a critical transition may also occur simultaneously, resulting in a correspondingly high current flow.

One or more embodiments provide a circuit suitable for use, for example, in a class D audio amplifier of the monolithic type having high switching frequency, with the capability of reducing the amount of power dissipated as a result of switching (e.g., due to the critical transitions discussed previously) while improving linearity.

One or more embodiments also facilitate reducing the number of components required for that purpose.

FIG. 2 shows a general circuit layout in one or more embodiments. In FIG. 2, the half-bridges HB1, HB2 (to which the drive signals In_pwm1, In_pwm2 are applied) are schematically represented as including respective high-side and low-side power transistors (e.g., power MOS transistors) H1, L1 (half-bridge HB1) and H2, L2 (half-bridge HB2), with respective intermediate nodes at which voltages Vout1, Vout2 are present.

These nodes (hereinafter, for brevity, Vout1, Vout2) are shown with the load (L) arranged between them, with the low-pass LC filters Lo1, C1 (half-bridge HB1) and Lo2, C2 (half-bridge HB2) also shown.

It will be appreciated that the load (L) and possibly the LC filter networks may be distinct elements from the embodiments.

The two nodes Vout1, Vout2 will hereinafter be referred to as the output nodes of the half-bridges HB1, HB2, even though, strictly speaking, they do not represent the output nodes O1, O2 of the device (D) (see, for example, FIG. 1) having the load (L) coupled between them.

According to one or more embodiments, an electrical line is provided linking the output nodes in HB1 and HB2 between the high-side transistor (H1, H2) and the low-side transistor (L1, L2), that is, the nodes/lines where the signals Vout1 and Vout2 occur.

The line between these nodes (for brevity, these two nodes will be identified as Vout1 and Vout2) comprises an inductance (Laux) and two switches (S1, S2). These may be controlled by respective signals (e.g., Cs1, Cs2) as discussed below.

The opposed terminals of Laux are coupled to S1 and S2; that is, Laux is set between S1 and S2. Consequently, switch S1 will control coupling of the inductance Laux with the output Vout1 (half-bridge HB1), and switch S2 will control coupling of the inductance Laux with the output Vout2 (half-bridge HB2).

The representation of FIG. 2 also includes two further capacitances (Caux1, Caux2) between the outputs Vout1, Vout2, respectively, and ground.

In one or more embodiments, the capacitances Caux1, Caux2 can be provided, at least in part, by the parasitic capacitances of the transistors H1, L1 (Caux1) and H2, L2 (Caux2), particularly when using DMOS transistors.

As shown in FIG. 2A, a DMOS macro-model which can be used to simulate the behavior of power MOSFET transistors such as double-diffused metal-oxide-semiconductor (DMOS) transistors, comprises: a gate-source capacitive element (Cgs) for determining switching behavior and transient response; a drain-source capacitive element (XC), which contributes to parasitic effects in the device, influencing high-frequency response and switching losses; and body effect diodes (DBD, SubBD), where the threshold voltage is influenced by the potential difference between the body (or substrate) (SUB) and the source terminal (S).

FIGS. 2B and 2C depict characteristic curves of operation of a silicon DMOS.

As shown in FIGS. 2B and 2C, the DC behavior of a DMOS device (e.g., with a drain-source voltage of about 5V) can be modeled similarly to an ideal switch, with almost all of its current (I_MC) flowing in the MOS channel when the current is positive (first quadrant of the characteristic). Conversely, when the current is negative (third quadrant), such modeling is no longer applicable, as diode currents (I_DBD and I_SubBD) can become significant, especially at high temperature.

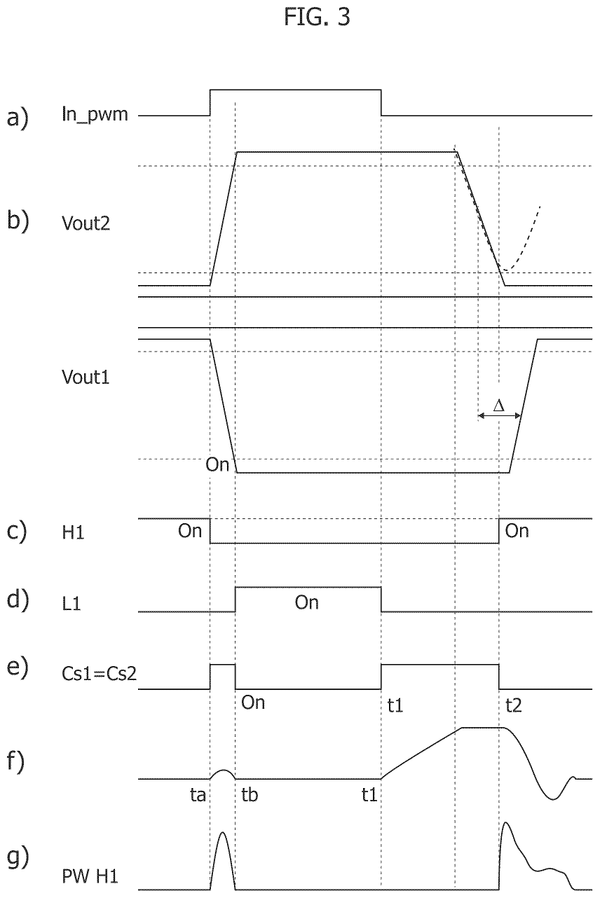

The diagrams in FIG. 3 illustrate possible time behavior of various signals in a ZSL circuit (per se known), where the presence of the aforementioned diode asymmetries is highlighted, assuming (as may reasonably be the case) complementary PWM-modulated behaviors of In_pwm1 and In_pwm2 (generally labeled In_pwm in portion a of FIG. 3).

In FIG. 3: In portion b), the behavior of the signal Vout2 is shown; the signal Vout1 will exhibit the same qualitative behavior in a complementary manner, that is, with Vout1 “low” when Vout2 is “high” and Vout2 “low” when Vout1 is “high,” except that the rising front of Vout1 is delayed by Δ with respect to the falling front of Vout2 due to the aforementioned body-diode asymmetries; Portions c) and d) show the on and off conditions of the low-side and high-side transistors (L1 and H1, respectively) in the half-bridge HB1; Portion e) shows possible control signals Cs1=Cs2 applied to the switches S1 and S2, assuming that an “On” value corresponds to the associated switch being made conductive; Portion f) illustrates possible time behavior of the current ILaux through the auxiliary inductance Laux; and Portion g) represents the power of DMOS H1 as the product of the voltage and the current flowing in high-side transistor H1 (due to body effects).

As shown in FIG. 3, at time instant t1, signal Vout1 is at the “low” logic value, and the circuit is configured to drive it towards the “high” logic state with a certain delay A with respect to a time instant when the corresponding signal Vout2 is driven low.

In a conventional solution, a control circuit manages the transition at time t1 by switching off L1 and H2 DMOS transistors through respective drivers while concurrently switching on the auxiliary control, resulting in conduction from Vout2 “high” to Vout1 through the auxiliary inductance Laux.

As shown in FIG. 3, at time t2, when signal Vout2 has switched to the “low” logic value, conventional solutions would switch off the auxiliary Laux and switch on high-side H1 and low-side L2, with Vout1 still low.

As shown in FIG. 3, in a ZSL Class D circuit as illustrated in FIGS. 2, the condition of having such front delay greater than the rise/fall time results in hard switching (high current-high voltage) of the DMOS as shown in FIG. 2A, thereby forcing the transition of the delayed output signal (H1 in FIG. 3), resulting in a significant power dissipation spike (PW H1 in FIG. 3).

It has been observed that introducing the possibility to drive low-side transistors L1, L2 separately from high-side transistors H2, H1, respectively, while maintaining auxiliary control signals Cs1 and Cs2, facilitates reducing power dissipation. At least one further driver signal is therefore introduced, which can be named H1d, H2d, L1d, and L2d.

As appreciated by those skilled in the art, at least in the audio-band frequency range, it may be possible to assume that amplifier input signals vary slowly compared to PWM timings.

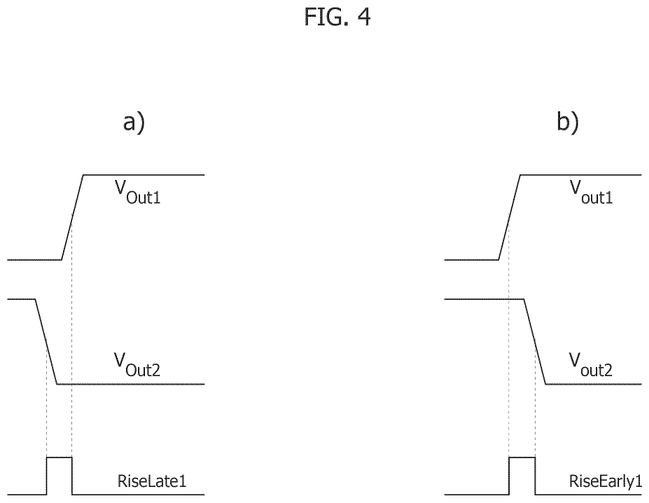

As described herein, a method of operating a ZSL circuit comprises measuring the delay A, including generating additional control signals RiseLate1 and RiseEarly1 based on output signals Vout1 and Vout2, as shown in FIG. 4.

For example: A first additional control signal (RiseLate1) indicates that the first rising edge of the first output signal (Vout1) is late with respect to (i.e., follows) the falling edge of the second output signal (Vout2); and A second additional control signal (RiseEarly1) indicates that the first rising edge of the first output signal (Vout1) arrives earlier with respect to (i.e., precedes) the falling edge of the second output signal (Vout2).

The additional control signals RiseLate1 and RiseEarly1 can be viewed as PWM signals having a temporal width based on the delay A.

For simplicity, the principles underlying one or more embodiments are discussed mainly with respect to exemplary scenarios in which:

In portion a) of FIG. 4, it is assumed that the delay A is present in the original ZSL circuit solely on one output signal, e.g., the one reverse conducting low (e.g., Vout1); as a consequence, the first additional control signal RiseLate1 has a first logic value (“1” or “true”), while the second additional control signal RiseEarly1 has a second logic value (“0” or “false”).

In portion b) of FIG. 4, it is assumed that the delay A is present in the original ZSL circuit solely on one output signal, e.g., the one reverse conducting low (e.g., Vout1 in FIG. 4); as a consequence, when the first additional control signal RiseLate1 has the second logic value, the second additional control signal RiseEarly1 has a first logic value.

As described herein, the method further comprises an integral control, generating a set of PWM signals (Del1, Del2) having the accumulated sum of the widths of one of the additional control signals minus the widths of the other additional control signal.

For example, generating a first PWM signal (Del1) of the set of PWM signals (Del1, Del2) comprises subtracting the width of the second additional control signal (RiseLate1) from the width of the first control signal (RiseEarly1), while generating a second PWM signal (Del2) comprises subtracting the width of the first additional control signal (RiseEarly1) from the width of the second control signal (RiseLate1).

The method further comprises delaying the switching off of the high-side transistor (e.g., H2 of the second half-bridge HB2) by the width of the first PWM signal (Del1), while also delaying switching off of the high-side transistor (e.g., H1 of the first half-bridge HB1) by the width of the second PWM signal (Del2), providing a set of delay control signals (H1d, H2d) to the transistor driver.

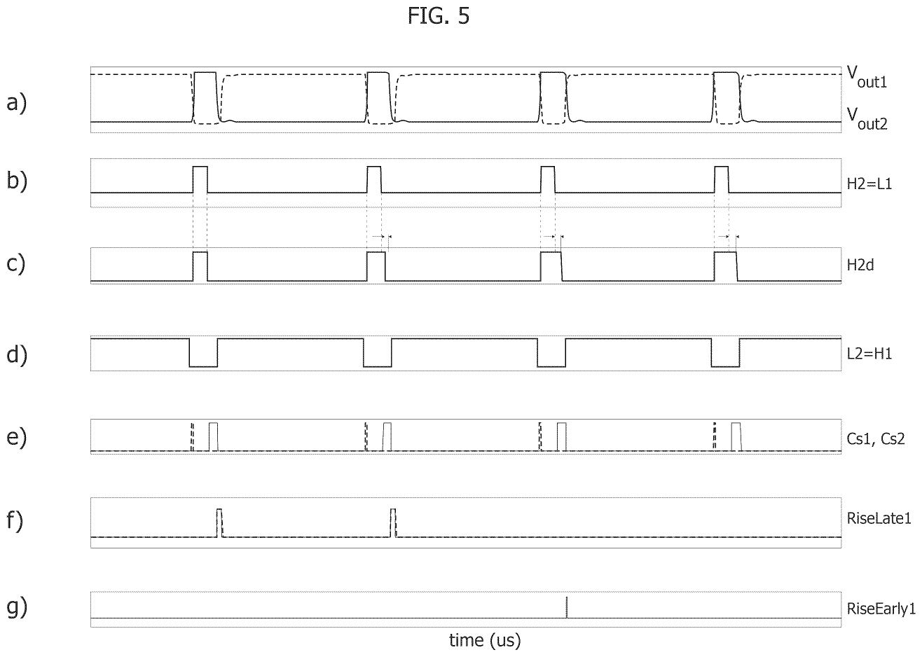

FIG. 5 is a diagram showing the evolution over time of signals suitable for use in one or more embodiments.

The diagrams in FIG. 5 illustrate possible time behavior of various signals in embodiments.

As shown in FIG. 5: In portion a), the behavior of the output signals Vout1, Vout2 is shown, with some differences visible in the transitions from “low” to “high” logic values (and vice versa) of the complementary signals; Portion b) shows the on and off conditions of the low-side transistor L1 of the first half-bridge HB1, which is the same as the high-side transistor H2 of the second half-bridge HB2; Portion c) shows the evolution over time of the second delay control signal H2d; Portion d) shows the on and off conditions of the low-side transistor L2 of the second half-bridge HB2 and high-side transistor H1 of the first half-bridge HB1; Portion e) shows possible control signals Cs1=Cs2 applied to the switches S1 and S2, assuming that an “On” value corresponds to the associated switch being made conductive; and Portions f) and g) show the evolution over time of the first additional control signal RiseLate1 and the second additional control signal RiseEarly1, respectively.

An exemplary scenario shown in FIG. 5 relates to a case in which, at the origin of the time axis, the current through the load of the arrangement shown in FIG. 1 is suddenly increased, resulting in output signal Vout1 having a rising front delay with respect to output Vout2, which conversely falls at the end of the first PWM period.

As shown in FIG. 5, thanks to the presence of the additional control signal H2d as the driving signal for the high-side transistor H2 of the second half-bridge HB2, the latter remains turned on while the Laux circuit is conducting. Such an arrangement forces output signal Vout2 to remain at the logic value “high” until a specific value of the delay is reached, which causes output signal Vout2 to synchronize its turn-off with the turn-on of Vout1.

As described herein, the method reaches a stable operating condition via successive approximations, using iterative feedback to gradually adjust the delay by reducing the width of the additional control signals RiseLate1 and RiseEarly1. For example, the correction at the Nth pulse comprises the delay measured and accumulated over previous pulses. In a reasonable scenario in which load current variation can be considered negligible with respect to a period (Tpwm) of the PWM signals, a stable delay adjustment is reached in the time of a few PWM cycles.

In a worst-case scenario in which the adjustment of the delay values presents a delay, so that reaching a compensating value takes some time (e.g., due to additional control signals RiseLate1 exceeding a threshold width), the driver of the high-side transistors HS1, HS2 can enter a safe driver operation mode in which the front edges of output signals Vout1, Vout2 slow down, for example by reducing the current for driving the high-side gate to the high logic state. In such a safe mode operation, the slope dV/dt of the output voltage Vout can be controlled and limited even in the case of fast current release from the DBD diode of the low-side transistors LS1, LS2.

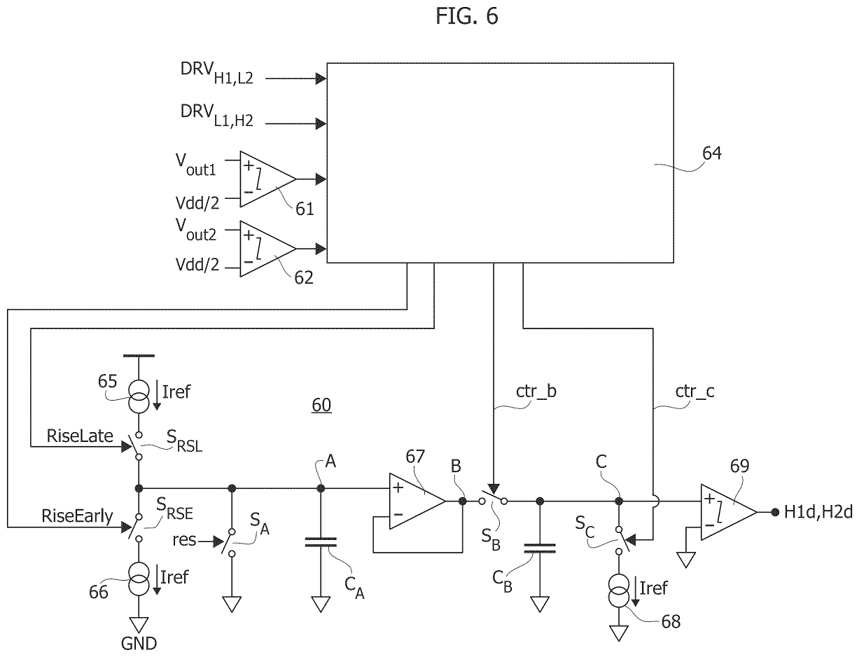

FIG. 6 is a diagram illustrating a circuit (60) operating according to the method described herein.

As shown in FIG. 6, the circuit 60 is based on a conversion from time (e.g., pulse width) to voltage, using capacitors as charge storage, current generators, and switches.

The circuit 60 comprises: a first comparator (61) having a first input node configured to be coupled to the first output node Vout1 of the first half-bridge HB1 (see, e.g., FIG. 2) to receive the first output signal Vout1, and a second input node configured to be coupled to a reference voltage level Vdd/2, equal to half the supply voltage Vdd of the half-bridge HB1; the first comparator 61 performs a comparison of the first output signal Vout1 and the reference voltage level Vdd/2, providing the result to a logic circuit block (64); a second comparator (62) having a first input node configured to be coupled to the second output node Vout2 of the second half-bridge HB2 (see, e.g., FIG. 2) to receive the second output signal Vout2, and a second input node configured to be coupled to a reference voltage level Vdd/2, equal to half the supply voltage Vdd of the half-bridge HB2; the second comparator 62 performs a comparison of the second output signal Vout2 and the reference voltage level Vdd/2, providing the result to the logic circuit block (64); the logic circuit block (64) is coupled to the first comparator (61) and the second comparator (62) to receive the comparison signals, and further coupled to a set of switches (SRSL1, SRSE1, SA, SB, SC) to provide a respective set of switch control signals (RiseLate, RiseEarly, res, ctr_b, ctr_c); reference current generators (65, 66, 68) are coupled to respective switches (SRSL1, SRSE1, SC) and configured to provide reference currents (Iref) along a current flow line towards ground (GND); an operational amplifier stage (67), such as a buffer, having a first input node (+) coupled to an intermediate node (A) interposed among the switches (SRSL, RRSL, SA), and a second input node (−) coupled to an output node (B); a first capacitive element (CA) coupled to the intermediate node (A) and a second capacitive element (CB) selectively couplable to the output node (B) of the amplifier (67) via the switch (SB); a third comparator (69), for example a window comparator, having an input node coupled to a node (C) of the second capacitor (CB) referred to ground (GND) and a second input node coupled to ground (GND), the third comparator (69) configured to provide additional control signals (H1d, H2d) to the drivers of the power stages H1, L2 of the half-bridge arrangements HB1, HB2.

Among the switches in the set (SRSL1, SRSE1, SA, SB, SC): the first switch (SRSL) is configured to selectively couple reference current generator (65) to node (A) based on control signal (RiseLate) received from the control logic (64); the second switch (SRSE) is configured to selectively couple reference current generator (66) to node (A) based on control signal (RiseEarly) received from the control logic (64); the third switch (SA) is configured to selectively couple node (A) to ground (GND) based on a reset control signal (res); the fourth switch (SB) is configured to selectively couple nodes (B) and (C) based on control signal (ctr_b) received from the control logic (64); and the fifth switch (SC) is configured to selectively couple node (C) to reference current generator (68) based on control signal (ctr_c) received from the control logic (64).

A method of operating the circuit 60 comprises: performing a comparison (61, 62) of at least one output signal (Vout1, Vout2) from respective half-bridge circuits (HB1, HB2) and a threshold value (Vdd/2), obtaining at least one delay control signal (RiseLate, RiseEarly) as a result of the comparison; converting to a voltage level the width of the part of the signal at a logic “high” value of at least one delay control signal (RiseLate), for instance by charging capacitor (CA) via one of the reference current generators (65, 66) which is coupled thereto as a result of the comparison; and converting to a voltage level the width of the part of the signal at a logic “high” value of at least one delay control signal (RiseEarly), for instance by discharging capacitor (CA) with the same reference current (Iref).

The method further comprises: transferring the voltage on the first capacitor (CA) to the second capacitor (CB) (e.g., via voltage buffer (67)), andconverting the voltage signal to a delay, for example, by discharging the second capacitor (CB) using the same reference current (Iref); applying the converted delay (A) to a falling edge/front of a respective drive signal (e.g., DRVH2, generating second additional control signal (H2d) or DRVH1, generating additional control signal (H1d)).

Therefore, thanks to the circuit 60, a delay (A) is introduced, in an iterative manner, in the turn-on of H2 as a function of the delay between Vout1 and Vout2, thereby finely synchronizing the signals and improving the overall performance of the ZSL power stage illustrated in FIG. 1.

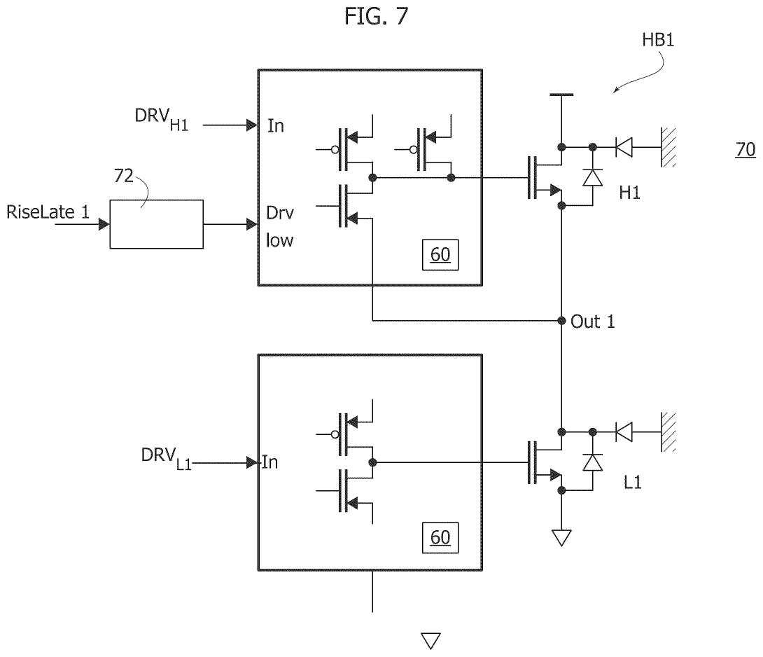

As shown in FIG. 7, to implement a “safe driver” operating mode, the circuit 60 can be arranged in parallel to a filter circuit (72) configured to detect any abrupt variation of the time-distance among fronts of signals Vout1, Vout2 (e.g., above 10 ns). For instance, the filter circuit (72) is coupled to driver-generating amplification circuitry (74) comprising a plurality of power stages. In response to the filter circuit (72) indicating that the delay among the signal fronts Vout1, Vout2 is greater than a threshold, a reduced number of power stages are activated for the driver-generating amplification circuitry (74), thereby reducing the drawbacks of the introduced hard-switching which can be difficult to compensate in a few iterations of the compensation method discussed above.

The filtered signal from block (72) controls output stage activation (e.g., two stages or more depending on the specific driver architecture), limiting the current available to drive the high-side gate in conduction.

A second exemplary method, circuit, and device according to the present disclosure is illustrated in FIGS. 1, 2, 2A, 2B, 2C, and 8 to 13.

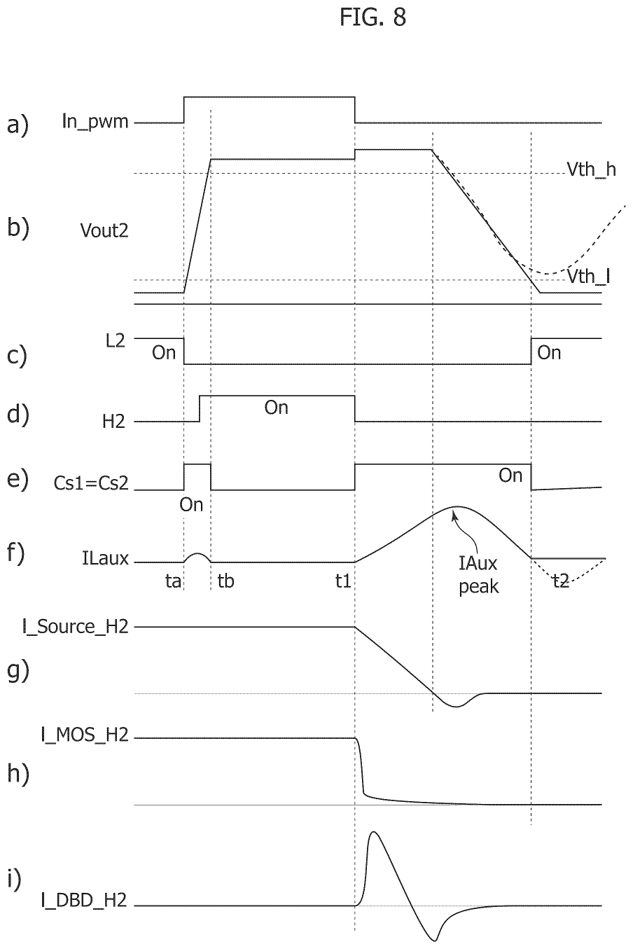

FIG. 8 comprises diagrams of the evolution over time of signals suitable for use in one or more embodiments.

In the following, one or more embodiments are discussed mainly with reference to a situation in which the previously discussed delay is neglected for simplicity. Therefore, the following discussion mainly relates to exemplary scenarios in which the lack of synchronization of output signal fronts Vout1, Vout2 can be neglected, either because already compensated as discussed below or because negligible with respect to other parasitic effects.

As shown in FIG. 8, because of the DBD and SubBD effects, the second output voltage Vout2 reaches a logic “high” value (e.g., at time instant tb) while a current (I_MC) is flowing through the high-side (HS2) of the second half-bridge HB2. In other words, the exemplary scenario represented in FIG. 8 refers to a case in which the high-side transistor HS2 of the second half-bridge HB2 illustrated in FIG. 2 is conducting in reverse mode (e.g., from time instant tb to time instant t1 in FIG. 8).

As used herein, the term “hard switching” designates an output transition starting with the switching off of one main reverse conducting DMOS (in FIG. 8 between t1 and t2) that may occur in a ZSL or non-ZSL Class D amplifier. Conversely, a transition starting with the switching off of a forward conducting DMOS (in FIG. 8 between ta and tb) is called “soft switching.”

FIG. 8 depicts a waveform of a ZSL amplifier occurring when the current load is greater than the ripple current, so that one commutation (the first one illustrated in the Figure, for instance) is related to soft switching, and the next one is related to hard switching.

In FIG. 8:
In portion a), the evolution of driver signal In_pwm is represented; such a signal can be equal, for example, to the driver In_pwm2 for the second high-side transistor H2 and in quadrature with the driver signal In_pwm1 for the first high-side transistor H1;
In portion b), the behavior of the signal Vout2 is shown;
Portions c) and d) show the on and off conditions of the second low-side and second high-side transistors (L2 and H2, respectively) in the second half-bridge HB2;
Portion e) shows possible control signals Cs1=Cs2 applied to the switches S1 and S2 illustrated in FIG. 1, assuming that an “On” value corresponds to the associated switch being made conductive;
Portion f) illustrates possible time behavior of the current ILaux through the auxiliary inductance Laux;
Portion g) represents the evolution over time of a current Is (e.g., see FIG. 2A) flowing from the source terminal of the second high-side transistor H2 of the second half-bridge HB2;
Portion h) represents a current I_Mc (see, e.g., FIG. 2A) through the MOS channel of the second high-side transistor H2 of the second half-bridge HB2;
Portion i) shows the evolution over time of a diode current I_DBD (see, e.g., FIG. 2A) through the body diode of the second high-side transistor H2 of the second half-bridge HB2.

As shown in FIGS. 2B and 8, current in steady-state conditions is partitioned depending on temperature into three components: the one in the main MOS channel, the one in the DBD diode, and the one in the SubBD diode (the latter is zero for a high-side transistor).

During the same time interval, the transistors in the first half-bridge arrangement HB1 are in a complementary condition: a current of the same magnitude Is is coming out from the source terminal of the low-side transistor L1, which is conducting in reverse mode.

For simplicity, one or more embodiments are discussed mainly with reference to the second half-bridge arrangement HB2, it being understood that one or more embodiments can apply to the first half-bridge arrangement HB1 mutatis mutandis.

As appreciated by those skilled in the art, a reverse conduction condition of the power transistors can be identified by the current sign and the output PWM voltage.

As shown in FIG. 8, at time instant t1, the auxiliary switches S1, S2 are switched on (see control signals Cs1=Cs2) while the high-side switch H2 is turned off at the same time (drive signal H2). Even in a hypothetical case in which a very fast turn-on of the auxiliary switches S1, S2 can be contemplated, the auxiliary inductor Laux may represent a bottleneck, as its increase can hardly be instantaneous for a finite voltage applied. Therefore, the current mainly flows in the DBD diode of the high-side transistor H2 since the threshold voltage Vgs is being switched off.

If the device temperature is high enough (e.g., higher than room temperature) and the rising time Tdel_Main is equal to or greater than the reverse recovery time of a DBD diode, the scenario represented in FIG. 8 could contemplate the possibility that the DBD diode is already conducting a positive current before time t1 even if gate-source voltage Vgs is above the threshold. In any case, a DBD current increase will happen after t1, as shown in portion i) of FIG. 8.

For simplicity, one or more embodiments are discussed primarily with respect to the ZSL circuit architecture illustrated in FIG. 1, it being understood that such an architecture is purely exemplary and not limiting. One or more embodiments may apply to any ZSL circuit architecture mutatis mutandis.

As shown in FIG. 2A, the charge stored in the diodes DBD, SubBD of a DMOS device can vary with temperature. Moreover, as shown in FIG. 8, there can be other dependencies from the exact timing of switching off and on of the switches, the inductance value Laux, and output capacitance value Cout.

It has been observed that by decoupling control signals Cs1 and H2 and controlling their timing, it is possible to reduce DBD conduction of H2, that is, the current I_DBD_H2 shown in portion i) of FIG. 8.

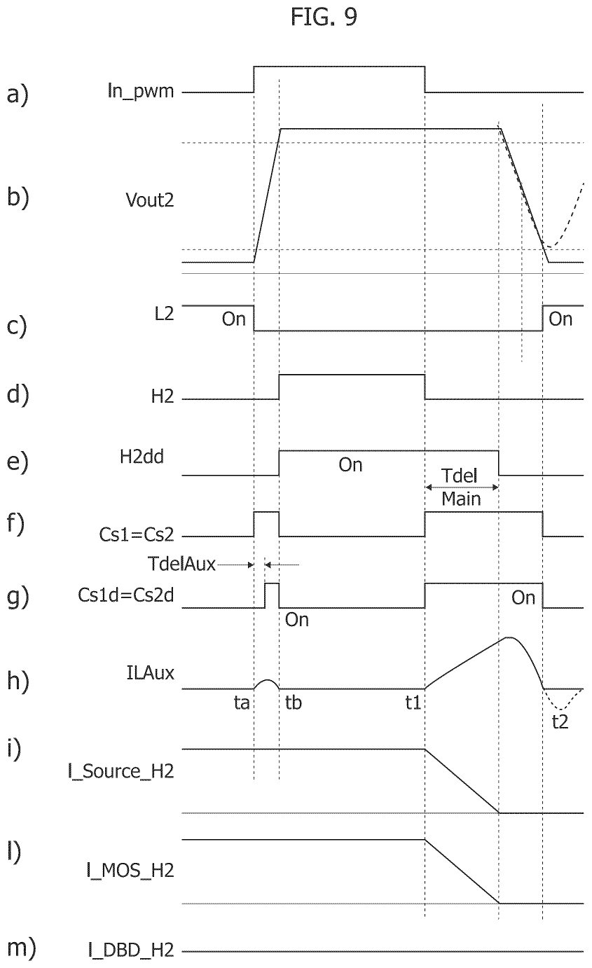

Such an exemplary scenario is represented in FIG. 9, where:
In portion a), the evolution of driver signal In_pwm is represented; such a signal can be equal, for example, to the driver In_pwm2 for the second high-side transistor H2 and in quadrature with the driver signal In_pwm1 for the first high-side transistor H1;
In portion b), the behavior of the signal Vout2 is shown;
Portions c) and d) show the on and off conditions of the second low-side and second high-side transistors (L2 and H2, respectively) in the second half-bridge HB2;
Portion e) shows a further control signal H2dd which can be provided to the second high-side transistor control node to reduce the charge Qrr stored in body diodes and related effects;
Portion f) shows possible auxiliary control signals Cs1=Cs2 according to the prior art;
Portion g) shows modified auxiliary control signals Cs1d=Cs2d configured to be applied to the switches S1 and S2 illustrated in FIG. 1, assuming that an “On” value corresponds to the associated switch being made conductive;
Portion h) illustrates possible time behavior of the current ILaux through the auxiliary inductance Laux;
Portion i) shows the evolution over time of a current I_source_H2 flowing from the source terminal of the second high-side transistor H2 of the second half-bridge HB2;
Portion l) shows a current I_MOS_H2 through the MOS channel of the second high-side transistor H2 of the second half-bridge HB2;
Portion m) shows the evolution over time of a diode current I_DBD_H2 through the body diode of the second high-side transistor H2 of the second half-bridge HB2.

A method of reducing a current flowing in the body diode comprises:
providing separate control signals CS1d, CS2d for the auxiliary switches S1, S2 and further control signals H1dd, H2dd for the high-side transistors H1, H2;
in response to a high-side transistor H1, H2 entering a reverse conduction state, introducing a delay in the turn-off of the high-side transistor H1, H2, for instance by introducing a delay in Tdel as shown in portion f) of FIG. 9; such a delay with respect to control signal Cs1, Cs2 for the auxiliary switches S1, S2 facilitates countering the increase of DBD current, as shown in portion m) of FIG. 9.

The method further comprises selecting the value of the delay Tdel to be equal to the time interval it takes for the auxiliary current ILaux flowing through the auxiliary inductance Laux to reach the same intensity as the current of the main inductor L illustrated in FIGS. 1 and 2 (e.g., reaching optimal pre-charging condition).

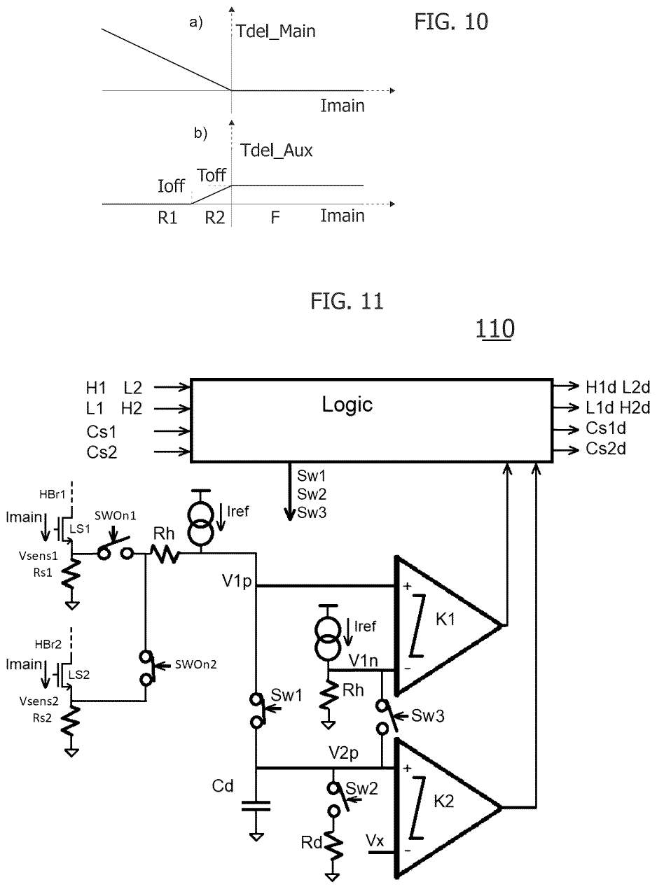

Portion a) of FIG. 10 illustrates a plot (intensity of source current Is on the abscissa scale in Ampere units, main power delay time Tdel_main on ordinate scale in seconds) of the delay to apply to the main control signal (e.g., driver of the second transistor H2) to obtain the further control signals Hldd, H2dd.

For simplicity, one or more embodiments are discussed herein with respect to an exemplary case in which it is assumed that the auxiliary gate switching time (e.g., TgAux) is equal to the switching time of the DMOS gate of the transistor (e.g., TgMain=TgAux).

In such an exemplary case, the time delay Tdel_Main illustrated in FIG. 10 can be expressed as: Tdel_Main=−Is×Laux/(Vdd−2×Vdrop) where: Is represents the output current in the high-side power (e.g., H2) just before t1 (negative sign because in reverse), Laux is the value of the inductance of the auxiliary inductance Laux, Vdd is the supply voltage, and Vdrop is the voltage drop across one auxiliary switch (usually composed of two DMOS) and one main DMOS turned on and having a current flow Iload through it.

As shown in FIG. 9 and the left side (negative abscissa) of FIG. 10, in an exemplary scenario in which the current Is coming from the output, before time instant t1, enters the second high-side transistor H2 and the first low-side transistor L1 in reverse mode (with the transistor turned on by having a voltage Vgs applied to the control nodes). In such an exemplary scenario, if the on-resistance of the power stages H2, L1 is adequate, at low temperature the current Is flows mainly through the MOS channel of the respective transistors.

After time instant t1, the gate-source of the transistors H2, L1 is kept “high” until the current in the auxiliary switches S1, S2 of the circuit illustrated in FIG. 2 increases, reaching the output value Iout. In response to reaching such a condition, after a delay time Tdel_Main from time instance t1, the current in the MOS channel becomes almost negligible. In response to the gate-source voltage Vgs being removed (therefore, with the transistors switched off), no current affects the DBD and SubBD diodes. In such an exemplary scenario, in case of high temperatures that might introduce a positive DBD current before time instance t1, such an increase of DBD current is countered after time instance t1. Therefore, at the end of the method operations, DMOS reverse recovery is reduced to a minimum.

Portion b) of FIG. 10 is a plot (source current intensity Is on abscissa scale in Ampere units, auxiliary delay Tdel_aux on ordinate scale in seconds) which illustrates how to determine the delay to introduce to provide additional auxiliary control signals Cs1d, Cs2d starting from control signals Cs1, Cs2 and taking into account a more refined scenario.

As shown on the right side (positive abscissa) of FIG. 10, in response to the high-side switch entering a forward-conductive stage (as shown in FIG. 8, corresponding to the time instant ta, that is, at the soft switching transition): the output switching is driven by the main current right after switching off L2 and H1. Therefore, the auxiliary switches S1, S2 are switched on after a time lapse sufficient for the switching off of the main DMOS H2 in order to counter spurious conduction from L2 and H1 through auxiliary switches S1, S2, which would result in unnecessary dissipation.

During the time interval ta-tb, the method comprises delaying the auxiliary control signals Cs1, Cs2 to be applied to auxiliary switches S1, S2 by a quantity TdelAux=Toff, which is selected in order to avoid auxiliary cross conduction.

According to the original ZSL circuit, during the time interval ta-tb, the switching off of L1 and H1 is done with zero delay after time instant ta, and the switching on of H2 and L1 starts at tb, corresponding to Vout2 having risen sufficiently (or Vout1 having fallen sufficiently) for the respective comparator to switch.

For example, to facilitate a smooth transition between the case of high forward current (right side of FIG. 10, labeled F) and high reverse current (left side of FIG. 10, labeled R1), the “intermediate” case (labeled R2) is managed as follows: In a first exemplary case, shown in the left portion a) of FIG. 10, in which the current flowing from the source Is of the high-side H2 is negative before switching power off, a delay Tdel_main is applied to the switching off of the main transistor (which can be expressed as Tdel_Main=−Is×Laux/(Vdd−2×Vdrop)), while an auxiliary delay Tdel_aux, shown in the left portion b) of FIG. 10, can be reduced from Toff proportionally to the current until it reaches zero.

In such a scenario, the auxiliary delay Tdel_aux can be expressed as: Tdel_Aux=Max[0, Toff+Imain×Laux/(Vdd−2×Vdrop)] where Imain is negative.

The value of Imain current at which Toff+Imain×Laux/(Vdd−2×Vdrop)=0 is called Ioff. It follows that: abs(Ioff)=Toff×((VCC−2×Vdrop)/Laux) For example, in a different scenario in which the source current is positive, the main delay is reduced to zero (e.g., Tdel_Main=0), while an auxiliary delay Tdel_aux can be applied to the auxiliary control signals Cs1, Cs2, with the auxiliary delay equal to a given value Toff (which can be increased as much as the main driver delay Tdel_main eventually increases with the current).

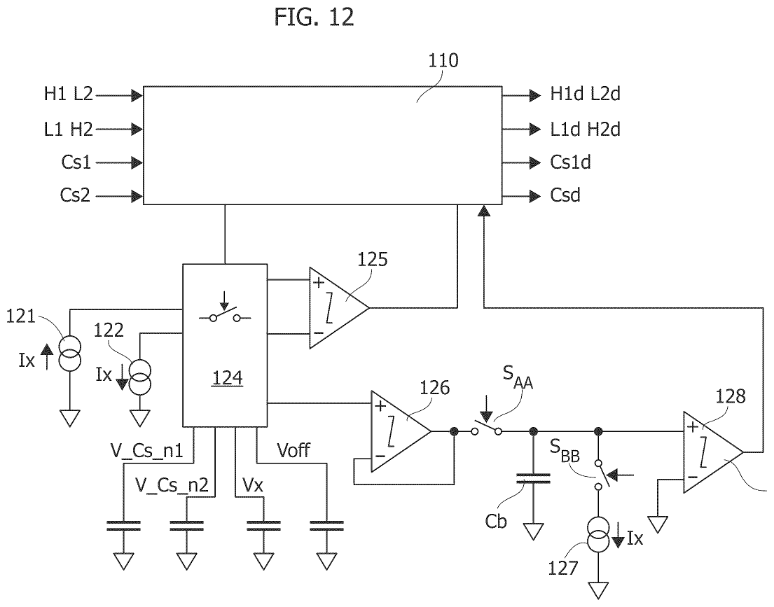

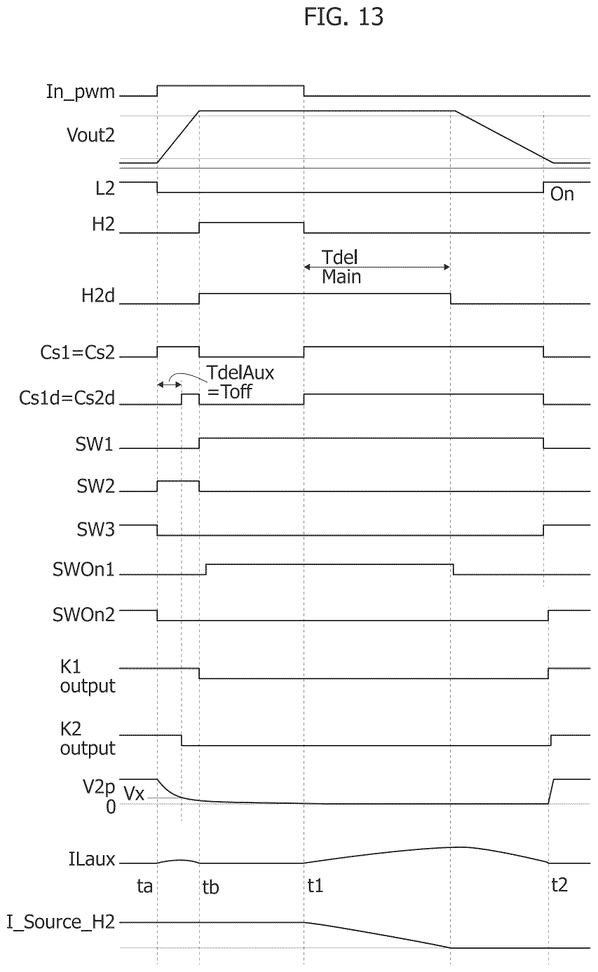

FIGS. 11 and 12 are diagrams showing one or more circuits configured to implement the control method discussed above with reference to FIGS. 8 to 10.

For simplicity, one or more embodiments are discussed mainly with reference to a circuit for providing separate Cs2 and additional H2dd control signals for the second auxiliary switch S2 and the second high-side transistor H2, it being understood that such an example is purely exemplary and not limiting, as the circuit 110 can be used mutatis mutandis for any other transistor in the half-bridge arrangement.

As shown in FIG. 11, a circuit 110 comprises: a set of current sensing arrangements configured to measure the respective voltage drops Vsens1, Vsens2 across respective low-side DMOS transistors LS1, LS2 of the half-bridges HB1, HB2 (e.g., by sensing the voltage at the metal connection at the source terminal, as in FIG. 11, or on its drain-to-source voltage on Ron during DMOS channel conduction, as shown with resistive elements Rs1, Rs2 of equal value Rs); and a reference resistance Rh coupled to a reference current generator 114 configured to provide reference current Iref, the reference resistance Rh being selectively couplable (e.g., via switches Swon1, Swon2) to the sensing nodes Vsens1, Vsens2; quantitatively, Rh>>Rs, Iref<<Max(Imain).

For example, the value of Iref and Rh is related to the absolute value of Ioff defined above, described in section b of FIG. 10, by the following equation: Iref×Rh=|Ioff|×Rs=Vref

Switches SWon1 and SWon2 are configured to couple each respective sensing arrangement to the respective low-side DMOS LS1, LS2 when the latter is conducting (e.g., while the current in reverse conduction is passing mainly through the MOS channel during conduction). For example, switches Swon1, Swon2 are configured to be driven based on output PWM sign (e.g., turn on Swon1 when Out1 is “low”, turn on Swon2 when Out2 is “low”). Given a certain load current and a certain duty cycle D, each PWM cycle, the amplifier shown in FIG. 2 presents a first conductive diagonal path among DMOS transistors (e.g., among first low-side L1 and second high-side H2) for a time approximately Tpwm×D and a second conductive diagonal path among DMOS transistors (e.g., among first high-side H1 and second low-side L2) for a time Tpwm×(1−D).

The circuit 110 further comprises: a first comparator circuit 112 having a first comparator input node coupled to the voltage node V1p and a second comparator input node coupled to voltage node V1n, interposed with a further reference current generator 114 and a replica of reference resistance Rh, thereby providing reference voltage level Vref at the second comparator node; the first comparator circuit 112 is further configured to provide at a comparator output node K1 the difference among signals at input nodes; and a second comparator circuit 114 having respective comparator input nodes coupled to a second voltage node V2p and to V2n=Vx, where Vx is a small fixed voltage threshold, e.g., equal to a fraction of Vref, the second comparator circuit 114 is further configured to provide at a comparator output node K2 the difference among input nodes V2p, V2n.

The voltage node V1p is selectively couplable, via first switch Sw1, to a capacitive element Cd referred to ground GND. The voltage node V2p is coupled to the capacitive element Cd and is selectively couplable, via second switch Sw2, to a resistive element Rd referred to ground GND. A third switch Sw3 is configured to selectively couple the voltage node V1n at the second input node of the first comparator 112 to the voltage node V2p at the first input node of the second comparator 114.

The circuit 110 further comprises a logic circuit block 110 coupled to the high-side switch driver H2, to the auxiliary switch driver Cs2, and to comparators 112, 114, the logic circuit block 110 configured to apply respective delays Tdel_main, Tdel_aux based on the received output signals from comparators 112, 114, thereby providing separate Cs1d and additional H2dd control signals to the circuit shown in FIG. 2.

A method of operating the circuit 110 comprises: sensing the (e.g., source) current Is from low-side transistors L1, L2 by measuring the respective voltage drop Vs1, Vs2 on the respective sense resistance Rs1, Rs2 (representing a metal connection at the source terminal, as in FIG. 11, or on its drain-to-source voltage on-resistance Ron during VGS-ON DMOS channel conduction); when switches Sw2 and Sw3 are open, and Swon1 or Swon2 are closed, shifting the value of the sense voltage (e.g., Vs1=Vs2=Vsens) by superimposing, at node V1p, a reference current Iref<<MAX|Imain| across the known resistor Rh; in an exemplary case in which Rs1=Rs2=Rs, it is possible to implement a level shifter adding a small positive entering Iref on such known resistor Rh. The node voltages V1p and V1n can be expressed as:

$$( Imain + Iref ) \cdot Rs ≅ Imain \cdot Rs = Vs 1 = Vs 2 = Vsens$$

$$Iref \cdot Rh = \vert Ioff \vert \cdot Rs = Vref$$

$$V 1 p = Imain \cdot Rs + Iref \cdot ( Rh + Rs ) ≅ Vsens + Vref$$

$$V 1 n = Iref \cdot Rh = Vref$$

$$where$$

$$Ioff = Toff \cdot ( ( VCC - 2 Vdrop ) / Laux )$$

The method further comprises: performing a first comparison via first comparator 112, where its input node difference can be expressed as:

$$V 1 p - V 1 n ≅ Vsens$$

As a result, the first comparator 112 provides to the logic circuit 110 a signal indicative of the sign of the sensed current Is.

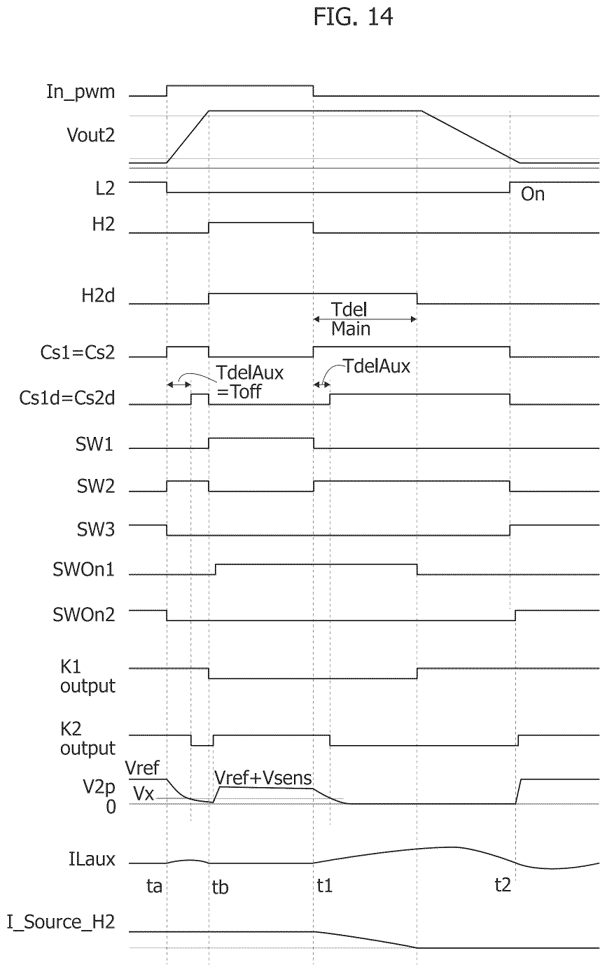

As shown in FIGS. 13 and 14:
In a first time interval tb−t1 (just before the drive signal In_pwm switches from “high” to “low”), switch SWon1 is turned on (closed), coupling first sensing node Vsens1 to the input node V1p of the first comparator 112 through Rh;
In the scenario shown in FIG. 13, the output K1 of the first comparator 112 is indicative of a negative sign of Vsens1 (DMOS reverse conduction); in such a scenario, the logic circuit 110 is configured to provide control signals Sw1, Sw2, Sw3 to respective switches so that, neglecting the transient effect of capacitor Cd charging, the first switch Sw1 is on (closed), the second switch Sw2 is off (open), and the third switch Sw3 is off (open); the differential input at the second comparator 114 is equal to the voltage Vref+Vsens−Vx, where Vsens is negative.
In a second time interval t2-ta (just before the drive signal In_pwm switches from “low” to “high”), switch SWon2 is turned on (closed), coupling second sensing node Vsens2 to the input node V1p of the first comparator 112 through Rh;
In the scenario shown in FIGS. 13 and 14, the output K1 of the first comparator 112 is indicative of a positive sign of Vsens2 (DMOS forward conduction); therefore, starting from t2, the logic circuit 110 is configured to provide control signals Sw1, Sw2, Sw3 to respective switches so that the first switch Sw1 is off (open), the second switch Sw2 is off (open), and the third switch Sw3 is on (closed); the differential input at the second comparator 114 is equal to the voltage Vref−Vx.

At time t1 (when K1 is indicative of a negative current and drive signal In_pwm switches from high to low), if K2 output is equal to zero (because V2P=Vref+Vsens is lower than Vx), corresponding to FIG. 10—R1 zone (high negative current):
the logic circuit 110 is configured to provide control signals Sw1, Sw2, Sw3 to respective switches so that the first switch Sw1 is on (closed), the second switch Sw2 is off (open), and the third switch Sw3 is off (open);
auxiliary control signal Cs1 switches without any delay and the second high-side switch H2 remains turned on;
as a result, the current in the auxiliary inductance Laux increases while concurrently the current in the main inductance L decreases, until Vsens reaches zero;
in response to Vsens reaching zero, the output K1 of the first comparator 112 switches;
in response to such a switch of K1, the second high-side H2 is switched off.

At time t1 (when K1 is negative and drive signal In_pwm switches from high to low), if K2 is positive (because V2P is greater than Vx), corresponding to FIG. 10—R2 zone (small negative current):
the sensing current Isens, which is negative, is between Ioff and zero;
as a result, the second high-side H2 is kept turned on while the control logic is configured to drive the first switch SW1 to be off (open) and the second switch Sw2 to be on (closed);
as a result, the discharge of second node V2p is triggered and proceeds until reaching a proper threshold Vx (e.g., R2 can also be a fixed current generator) to generate a delay Taux_del approximately proportional to the difference (Vref−|Vsens|) to be applied to the auxiliary controls (Cs1d and Cs2d) to be provided to the auxiliary circuitry in the ZSL circuit arrangement shown in FIG. 2.

At time ta (when K1 is positive and drive signal In_pwm switches from high to low), K2 is positive and:
the control logic is configured to drive the first switch SW1 and the third switch Sw3 to be off (open) while the second switch Sw2 is closed; as a result, the capacitor Cd (previously charged at the max positive value Vref) is discharged through its network to take a time Toff to make K2 switch;
in response to the output signal switching, the second high-side switch H2 is turned on.

It is noted that, while one or more embodiments shown in FIG. 11 have been discussed mainly with reference to the use of current sensing on the power, the actuating switches are controlled based on the present value of the state variables.

FIG. 12 is a diagram showing an alternative circuit 120 to control the circuit 20 shown in FIG. 2.

With respect to circuit 110 shown in FIG. 11, the alternative circuit 120 is based on the hypothesis that amplifier input signals vary slower than PWM signals. Under such a hypothesis, the width of the auxiliary control signals Cs1, Cs2 can be used to provide an estimate Ix of the current Is flowing in DMOS power switches H1, H2 for the next switching event.

For example, when the power switches H1, H2 operate in reverse condition (also referred to as the third quadrant), the temporal width of auxiliary control signals Cs1, Cs2 is proportional to the time it takes the auxiliary inductance Laux to have the current flowing through it go from zero to a value ILaux=Is+Iboost+Tr. For example, a time T_Cs in which the auxiliary control signal Cs2 is at a first logic level can be expressed as:

$$T\_Cs1 = ( Iout + Iboost ) \cdot Laux / Vd + Tr$$

where:
is a quantity dependent on output fall/rise time, which varies slightly with the output current;
Iboost is an additional current configured to compensate diode reverse recovery charge; and
Iout is the sum of the load current plus the ripple current, which is dependent on the duty cycle.

As shown in FIG. 12, the alternative circuit 120 comprises:
current generators 121, 122;
at least one sample-and-hold (S&H) circuit 124 coupled to at least one current estimating node Ix and to a plurality of capacitive elements Cs_n−1, Cs_n−2, Cx, Coff configured to store respective voltages V_Cs_n−1, V_Cs_n−2, Vx, Voff as discussed below;
at least one comparator circuit 125 coupled to the S&H circuit 124 to perform at least one comparison of stored voltages V_Cs_n−1, V_Cs_n−2, Vx, Voff, as discussed below, and to provide the result(s) of the at least one comparison to the control logic circuit 110;
a buffer 126 coupled to the S&H circuit 125 to receive stored voltage values;
a buffer capacitive element Cb referred to ground GND and being selectively couplable to the output of the buffer 126 via switch Saa driven by a respective control signal from the control logic 110;
a further comparator circuit 128 having a first input node coupled to the buffer capacitive element Cb and a second input node coupled to ground GND, the further comparator circuit 128 configured to provide a delay signal Del1 to the control logic 110 to be applied to auxiliary Cs2 and main H2 driver signals, providing separate Cs2d and delayed H2dd control signals as a result.

A common practice for converting a time pulse-width into a voltage (and vice versa) comprises charging/discharging a known capacitor with a known current based on the pulse-width length.

In the following, a compact notation is used for simplicity, wherein:
VCs_n−1=the time to voltage conversion of the (N−1)th pulse width auxiliary control signal Cs2 (e.g., in FIG. 9 equal to tb−ta);
VCs_n−2=the time to voltage conversion of the (N−2)th pulse width of auxiliary control signal Cs2 (e.g., equal to t2−t1 of the previous pulse);
Voff is a predefined voltage, which is the time to voltage conversion of Cs1 when the current Is=Ioff;
Vx is the time to voltage conversion of Tr, equal to the Cs1 width when the current Is=0.

It has been observed that the sign of the current at the nth pulse can be retrieved by pairwise comparing VCs_n−2 and VCs_n−1.

In a first exemplary scenario in which the result of the comparison yields that VCs_n−2 is greater than VCs_n−1, then the current at the nth pulse is estimated to be negative. As a result, the delay Tdel is applied to the driver signal H2 from time t1+, discharging a capacitor loaded at VCs_n−2 until reaching Vx, with the same current used to charge the same capacitors.

A buffer and a sample-and-hold can be used to store VCs_n−2 in the capacitor Cb, so that the process of loading the capacitor is consistent.

Still considering the case in which VCs_n−2>VCs_n−1, if also the condition VCs_n−2<Voff stands valid, this indicates that the regime ta-tb shown in portion b) of FIG. 10 applies. Therefore, the auxiliary control signal Cs2 is also delayed by an auxiliary delay Tdel_aux via the control logic 110, providing separate auxiliary control signal Cs2d. In other words, the rising front of auxiliary control signal Cs2 is delayed by the time it takes to discharge, via a controlled current, the voltage Voff until equating voltage VCs_n−2, in accordance with the expressions of Toff discussed above.

In an alternative case in which VCs_n−2<VCs_n−1, then the current at the nth pulse is positive (corresponding to the regime labeled as positive Is values after tb in portion b) of FIG. 10). Therefore, a delay is applied to the auxiliary control signal, but this time the delay is equal to the time it takes to completely discharge a capacitance loaded at Voff.

An advantage of the alternative circuit 120 shown in FIG. 12 compared to that of FIG. 11 is the possibility to save current sensing circuitry by replacing it with time-to-voltage converting circuits.

One or more embodiments may employ both the method and circuit illustrated in FIGS. 1 to 7 and those shown in FIG. 8 to 11 or 12 in order to compensate for the parasitic effects due to body drain diodes of switches S1, S2, H1, H2 produced using DMOS technology.

Example 1. In a first example, a circuit comprises:
a switching circuit stage comprising first HB1 and second HB2 half-bridges, each comprising a high-side DMOS transistor (H1, H2) and a low-side DMOS transistor (L1, L2), with respective output nodes (Vout1, Vout2) between the high-side and low-side DMOS transistors, the output nodes configured for supplying an electrical load (L) via respective filter networks (Lo1, C1; Lo2, C2) between the output nodes and the load;
control circuitry (60) coupled to the switching circuit stage and configured to control Cs1, Cs2, RiseLate, RiseEarly switching sequences (In_pwm) of the high-side and low-side transistors in the first and second half-bridges, wherein a first pair of DMOS transistors comprising the high-side DMOS transistor in one half-bridge and the low-side DMOS transistor in the other half-bridge is switched to a non-conductive state, and a second pair of transistors comprising the high-side DMOS transistor in the other half-bridge and the low-side DMOS transistor in the one half-bridge is switched to a conductive state.

In the first example, the circuit comprises:
a current flow line between the output nodes in the first and second half-bridges, the current flow line comprising an inductance (Laux) having opposed terminals coupled to a first switch (S1) and a second switch (S2), the switches selectively switchable between a non-conductive state and at least one conductive state;
first and second capacitances (Caux1, Caux2; CparH1, CparL1, CparH2, CparL2) coupled with the output nodes of the first and second half-bridges.

The control circuitry is configured to switch H1d, H2d, the first and second switches, to the at least one conductive state at intervals (ta, tb; t1, t2) in said switching sequences between switching the first pair of DMOS transistors (H1, L2) to a non-conductive state and switching the second pair of DMOS transistors (L1, H2) to a conductive state.

The control circuitry is further configured to provide control signals (H1d, H2d) to switch at least one of the first and second switches based on at least one comparison signal indicative of a delay (A) between a first output signal at the first output node and a second output signal at the second output node.

Example 2. In a second example, the control circuitry comprises:
a set of comparators (61, 62) having respective first comparator input nodes coupled to output nodes of the first and second half-bridge circuits to receive the first and second output signals, the comparators having respective second comparator input nodes coupled to at least one reference voltage level (Vdd/2) as well as respective comparator output nodes coupled to a logic circuit block to provide at least one comparison signal indicative of the delay between the first output signal at the first output node and the second output signal at the second output node.

The logic circuit block is coupled to the set of comparators to receive the comparison signal(s), and the control circuitry further comprises a set of control switches (SRSL1, SRSE1, SA, SB, SC) coupled to the logic circuit block to receive a respective set of switch control signals (RiseLate, RiseEarly, res, ctr_b, ctr_c) based on the comparison signal(s).

Example 3. In a third example, the circuit further comprises:
a set of reference current generators (65, 66, 68) coupled to a first subset of control switches (SRSL, SRSE, SC), the reference current generators configured to provide reference currents (Iref) along a current flow line towards ground (GND);
an operational amplifier stage (67) having a first input node (+) coupled to an intermediate node (A) interposed among the first subset of control switches, the operational amplifier arranged as a buffer having a second input node (−) coupled to the amplifier output node;
a first capacitive element (CA) coupled to the intermediate node and a second capacitive element (CB) selectively couplable to the amplifier output node via a respective control switch (SB);
a third comparator (69), preferably a window comparator, having an input node coupled to one end (C) of the second capacitor referred to ground and a second input node coupled to ground, the third comparator configured to provide at least one additional control signal to at least one power stage of the half-bridge arrangement.

The control circuitry is configured to:
perform a comparison (61, 62) of at least one output signal from respective half-bridge circuits and a threshold value (Vdd/2), obtaining as a result at least one first switch control signal (RiseLate, RiseEarly);
based on the first switch control signal, charge (SRSL) or discharge (SRSE) the first capacitive element via a reference current provided by a reference current generator;
transfer (res, SA) the voltage on the first capacitive element to the second capacitive element via the operational amplifier stage;
discharge (ctr_b, SB) the second capacitor using the reference current (Iref) provided by a reference current generator;
provide (ctr_c, SC) to at least one power stage of the half-bridge arrangements the additional control signal based on the signal at the one end of the second capacitor referred to ground.

Example 4. In a fourth example, the set of control switches comprises:
a first switch (SRSL) configured to selectively couple a first reference current generator to the intermediate node based on a first control signal from the control logic;
a second switch (SRSE) configured to selectively couple a second reference current generator to the intermediate node based on a second control signal (RiseEarly) from the control logic;
a third switch (SA) configured to selectively couple the intermediate node to ground based on a reset control signal (res);
a fourth switch (SB) configured to selectively couple the amplifier output node and the signal at one end of the second capacitor based on control signal(s) (ctr_b) from the control logic;
a fifth switch (SC) configured to selectively couple the one end of the second capacitor to the third reference current generator based on a further control signal from the control logic.

Example 5. In a fifth example, the circuit comprises a filter circuit (72) configured to detect variation of the time-distance among fronts of signals and coupled to driver-generating amplification circuitry (74) comprising a plurality of power stages. For instance, in response to the filter circuit (72) indicating that the delay among the signal fronts is greater than a threshold, a reduced number of power stages are activated for the driver-generating amplification circuitry.

Example 6. In a sixth example, the control circuitry comprises:
a set of current sensing arrangements (Rs1, Rs2) configured to measure the respective voltage drops at respective sensing nodes (Vsens1, Vsens2) across respective low-side DMOS transistors of the respective half-bridges;
a reference resistance (Rh) coupled to a reference current generator (114) configured to provide reference current, the reference resistance being selectively couplable (Swon1, Swon2) to the respective sensing nodes;
a set of coupling switches configured to couple each respective sensing arrangement to the respective low-side DMOS during DMOS conduction;
a first comparator circuit (112) having a first comparator input node coupled to a first voltage node (V1p) and a second comparator input node coupled to a second voltage node (V1n) interposed with a further reference current generator (114) and a replica of reference resistance, thereby providing reference voltage level (Vref) at the second comparator node; the first comparator circuit is further configured to provide at a comparator output node (K1) the difference among its input signals, which is therefore equal to the sensing voltage (Vsens);
a second comparator circuit having respective comparator input nodes coupled to a third voltage node (V2p) and ground, the second comparator circuit being further configured to provide at a comparator output node (K2) the difference among its input nodes.

In the sixth example:
the first voltage node is selectively couplable, via a first control switch (Sw1), to a capacitive element (Cd) referred to ground;
the third voltage node is coupled to the capacitive element and is selectively couplable, via a second control switch (Sw2), to a resistive element (Rd) referred to ground;
the second voltage node is selectively couplable, via a third control switch (Sw3), to the third voltage node;
the control circuitry further comprises a logic circuit block (110) coupled to the high-side switch, to the auxiliary switch driver (Cs2), and to first and second comparators, the logic circuit block configured to apply respective delays (Tdel_main, Tdel_aux) based on the received output signals from comparators (112, 114), thereby providing separate Cs1d and additional H2dd control signals to at least one power stage of the half-bridge arrangements.

Example 7. In a seventh example, the set of current sensing arrangements (Rs1, Rs2) is configured to sense a voltage at a metal connection at a terminal of respective low-side DMOS transistors of the respective half-bridges during DMOS conduction.

Example 8. In an eighth example, the control circuitry comprises:
at least one sample-and-hold (S&H) circuit (124) coupled to at least one current estimating node (121, 122, Ix) and to a plurality of capacitive elements (Cs_n−1, Cs_n−2, Cx, Coff) configured to store respective voltages (V_Cs_n−1, V_Cs_n−2, Vx, Voff);
at least one comparator circuit (125) coupled to the S&H circuit to perform at least one comparison of stored voltages, providing as a result at least one comparison to a control logic circuit (110);
a buffer (126) coupled to the S&H circuit to receive stored voltage values;
a buffer capacitive element (Cb) referred to ground and being selectively couplable to the output of the buffer via a respective control switch (Saa) driven by a respective control signal from the control logic;
a further comparator circuit (128) having a first input node coupled to the buffer capacitive element and a second input node coupled to ground, the further comparator circuit configured to provide a delay signal (Del1) to the control logic to be applied to auxiliary Cs2 and driver signals, providing separate Cs2d and delayed H2dd control signals as a result.

Example 9. In a ninth example, the delay applied to the auxiliary control signal is equal to the time it takes to completely discharge a capacitance loaded at a respective stored voltage (Voff).

Example 10. In a tenth example, a device (D) comprises:
a PWM modulator (PWMM) configured (FN, LF) to receive an input signal (I/V in) and to produce therefrom first (In_pwm1) and second (In_pwm2) PWM-modulated drive signals,
a circuit according to any of examples 1 to 9 coupled with the PWM modulator, with the first and second half-bridges configured to be driven by said first and second PWM-modulated drive signals,
respective low-pass filter networks (Lo1, C1; Lo2, C2) coupled to the output nodes of the first and second half-bridges.

Example 11. In an eleventh example, the device comprises an electrical load (L) coupled to the circuit and supplied from the output nodes of the first and second half-bridges via said respective low-pass filter networks.

Example 12. In a twelfth example, a method of amplifying an input signal comprises:
applying an input signal to a PWM modulator in a device according to example 10 or 11, and
obtaining an amplified replica of the input signal at said respective low-pass filter networks coupled to the output nodes of the first and second half-bridges.

Without prejudice to the underlying principles, the details and embodiments may vary, even significantly, with respect to what has been described by way of example only, without departing from the extent of protection.

The extent of protection is determined by the annexed claims.

The claims are an integral part of the technical teaching provided herein with respect to the embodiments.

1. A circuit, comprising:
a switching circuit stage comprising first and second half bridges each comprising a high-side DMOS transistor and a low-side DMOS transistor, the first half bridge and the second half bridge each comprising respective first and second output nodes between their respective high-side DMOS transistor and their respective low-side DMOS transistor, the first and second output nodes configured for supplying an electrical load via respective filter networks coupled between the first and second output nodes and the load;
control circuitry coupled to the switching circuit stage and configured to control switching sequences of the high-side DMOS transistors and the low-side DMOS transistors in the first half bridge and the second half bridge;
wherein a first pair of DMOS transistors comprising the high-side DMOS transistor in one of the half bridges and the low-side DMOS transistor in the other of the half bridges is switched to a non-conductive state, and a second pair of transistors comprising the high-side DMOS transistor in the other of the half bridges and the low-side DMOS transistor in the one of the half bridges is switched to a conductive state;
a current flow line between the first and second output nodes in the first half bridge and the second half bridge, the current flow line comprising an inductance having opposed terminals coupled to a first switch and a second switch, the first switch and the second switch being selectively switchable between a non-conductive state and at least one conductive state, and
first and second capacitances coupled with the first and second output nodes of the first half bridge and the second half bridge;
wherein the control circuitry is configured to:
switch the first switch and the second switch to the at least one conductive state at intervals in said switching sequences between switching the first pair of DMOS transistors to a non-conductive state and switching the second pair of DMOS transistors to a conductive state; and
provide control signals to switch at least one of said first switch and said second switch based on at least one comparison signal indicative of a delay among a first output signal at said first output node and a second output signal at said second output node.

2. The circuit of claim 1, wherein the control circuitry comprises:
a set of comparators having respective first comparator input nodes coupled to the first and second output nodes of the first and second half-bridge circuits to receive the first and second output signals therefrom, the set of comparators having respective second comparator input nodes coupled to at least one reference voltage level as well as respective comparator output nodes coupled to a logic circuit block to provide said at least one comparison signal indicative of the delay among the first output signal at said first output node and the second output signal at said second output node;
wherein the logic circuit block is coupled to the set of comparators to receive the at least one comparison signal therefrom;
wherein the control circuitry further comprises a set of control switches coupled to the logic circuit block to receive therefrom a respective set of switch control signals based on said at least one comparison signal.

3. The circuit of claim 2, further comprising:
a set of reference current generators coupled to a first subset of control switches in the set of control switches, the set of reference current generators configured to provide reference currents along a current flow line towards ground;
an operational amplifier stage having a first input node coupled to an intermediate node interposed first subset of control switches in the set of control switches, the operational amplifier arranged as a buffer having a second input node coupled to the amplifier output node;
a first capacitive element coupled to the intermediate node and a second capacitive element selectively couplable to the amplifier output node via a control switch in the set of control switches;
a third comparator having an input node coupled to one end of the second capacitor referred to ground and a second input node coupled to ground, the third comparator configured to provide at least one additional control signal to at least one of the first and second half-bridges,
wherein the control circuitry is configured for:
performing a comparison of at least one of said output signal from the first and second half-bridges and a threshold value, obtaining as a result of the comparison at least one first switch control signal in the set of set of switch control signals;
based on the at least one first switch control signal, charging or discharging the first capacitive element via a reference current provided by a reference current generator in the set of reference current generators;
transferring the voltage on the first capacitive element to the second capacitive element via the operational amplifier stage;
discharging the second capacitor using said reference current provided by a reference current generator in the set of reference current generators; and
providing to at least one of the first and second half-bridges the at least one additional control signal based on the signal at the one end of the second capacitor referred to ground.

4. The circuit of claim 3, wherein the set of control switches comprises:
a first switch configured to selectively couple a first reference current generator in the set of reference current generators to said intermediate node based on a first control signal received from the control logic;
a second switch configured to selectively couple a second reference current generator in the set of reference current generators to said intermediate node based on a second control signal received from the control logic;
a third switch configured to selectively couple said intermediate node to ground based on a reset control signal;
a fourth switch configured to selectively couple amplifier output node and the signal at one end of the second capacitor therebetween based on control signal from the control logic;
a fifth switch configured to selectively couple the one end of the second capacitor to the third reference current generator based on a further control signal received from control logic.

5. The circuit of claim 1, comprising:
a filter circuit configured to detect variation of the time-distance among fronts of signals and coupled to driver-generating amplification circuitry comprising a plurality of half-bridges including the first and second half-bridges,
wherein, in response to the filter circuit indicating that a delay among the signal fronts is greater than a threshold, a reduced number of the plurality of half-bridges are activated for the driver-generating amplification circuitry.

6. The circuit of claim 1, wherein the control circuitry comprises:
a set of current sensing arrangements configured to measure respective voltage drops at respective sensing nodes across respective low-side DMOS transistors of the respective first and second half-bridges;
a reference resistance coupled to a reference current generator configured to provide reference current, the reference resistance being selectively couplable to the respective sensing nodes of the set of current sensing arrangements;
a set of coupling switches configured to connect each current sensing arrangement to its corresponding low-side DMOS transistor while that transistor is conducting;
a first comparator circuit having a first comparator input node coupled to a first voltage node and a second comparator input node coupled to a second voltage node, the second voltage node being connected through a further reference current generator and a replica of reference resistance, thereby providing a reference voltage level at the second comparator node;
the first comparator circuit being further configured to provide at a comparator output node the difference among its input signals, which is therefore equal to the sensing voltage; and
a second comparator circuit having respective comparator input nodes coupled to a third voltage node and ground, the second comparator circuit being further configured to provide at a comparator output node the difference among its input nodes;
wherein:
the first voltage node is selectively couplable, via a first control switch, to a capacitive element referred to ground;
the third voltage node is coupled to the capacitive element and is selectively couplable, via a second control switch, to a resistive element referred to ground; and
the second voltage node is selectively couplable, via a third control switch, to the third voltage node;
the control circuitry further comprising a logic circuit block coupled to the high-side switch, to the auxiliary switch driver, and to first and second comparators, the logic circuit block configured to apply respective delays based on the received output signals from comparators, thereby providing separate and additional control signals to at least one power stage of the half-bridge arrangements.

7. The circuit of claim 6, wherein each current sensing arrangement is configured to measure the voltage at a metal connection on a terminal of its corresponding low-side DMOS transistor in the respective half-bridge while that transistor is conducting.

8. The circuit of claim 1, wherein the control circuitry comprises:
at least one sample-and-hold (S&H) circuit coupled to at least one current estimating node and to a plurality of capacitive elements configured to store respective voltages;
at least one comparator circuit coupled to the S&H circuit to perform at least one comparison of stored voltages, providing as a result at least one comparison to a control logic circuit;
a buffer coupled to the S&H circuit to receive stored voltage values therefrom;
a buffer capacitive element referred to ground and being selectively couplable output of the buffer via a respective control switch driven by a respective control signal from the control logic;
a further comparator circuit having a first input node coupled to the buffer capacitive element and a second input node coupled to ground, the further comparator circuit configured to provide a delay signal to the control logic to be applied to auxiliary and driver signals, providing separate and delayed control signals as a result.

9. The circuit of claim 8, wherein the delay applied to the auxiliary control signal is equal to the time it takes to completely discharge a capacitance loaded at a respective stored voltage.

10. A device, comprising:
a PWM modulator configured to receive an input signal and to produce therefrom first and second PWM-modulated drive signals;
a circuit according to claim 1 coupled with the PWM modulator with the first and second half-bridges configured to be driven by said first and second PWM-modulated drive signals; and
respective low pass filter networks coupled to the first and second output nodes of the first and second half bridges.

11. The device of claim 10, further comprising an electrical load coupled to the circuit and supplied from the first and second output nodes of the first and second half-bridges via said respective low pass filter networks.

12. A method of amplifying an input signal, the method comprising:
generating first and second pulse-width modulated (PWM) drive signals from an input signal using a PWM modulator;
applying the first and second PWM drive signals to respective first and second half-bridges of a switching circuit, each half-bridge comprising a high-side DMOS transistor and a low-side DMOS transistor;
filtering the outputs of the first and second half-bridges using respective low-pass filter networks coupled to the output nodes of the half-bridges; and
delivering an amplified replica of the input signal at the outputs of the low-pass filter networks.

13. The method of claim 12, further comprising:
sensing a voltage across each low-side DMOS transistor in the first and second half-bridges during conduction, and
adjusting the timing of the PWM drive signals based on the sensed voltages to reduce switching losses.

14. The method of claim 12, wherein generating the first and second PWM drive signals comprises:
applying negative feedback from the outputs of the low-pass filter networks to the PWM modulator to improve linearity and reduce distortion in the amplified signal.

15. The method of claim 12, further comprising:
detecting a delay between rising or falling edges of the output signals from the first and second half-bridges; and
dynamically adjusting the activation of the half-bridges in response to the detected delay to prevent output overshoot.
